(19) United States
(12) Patent Application Publication
(10) Pub. No.: US 2017/0250099 A1
(43) Pub. Date: Aug. 31, 2017

(54) FILM STRESS UNIFORMITY CONTROL BY RF COUPLING AND WAFER MOUNT WITH ADAPTED RF COUPLING

(71) Applicant: EVATEC AG, Truebbach (CH)

(72) Inventor: Frantisek BALON, Buchs (CH)

(73) Assignee: EVATEC AG, Truebbach (CH)

(21) Appl. No.: 15/516,063

(22) PCT Filed: Oct. 13, 2015
(86) PCT No.: PCT/EP2015/073667

§ 371 Date: Mar. 31, 2017

Related U.S. Application Data
(60) Provisional application No. 62/063,478, filed on Oct. 14, 2014.

(51) Int. Cl. H01L 21/683

(52) U.S. Cl. CPC H01L 21/6833

(57) ABSTRACT

A fixture or clamp for a wafer in a vacuum treatment system has a non-conductive body with a first plane surface for arranging a substrate (wafer) thereon and a second surface opposite to first surface. A body includes a plurality of electrode-pairs; each electrode pair comprising a first electrode with a first electrode surface and a second electrode with a second electrode surface, electrode surfaces interconnected via a conductive member and arranged essentially in parallel to the first and second surfaces, the first electrode located closer to the first surface than the second electrode and the second electrode located closer to the second surface than the first electrode. Such a body can be used for RF coupling between the wafer and pedestal on RF potential to achieve a uniform film stress profile/distribution during film deposition or other substrate treatment.

This invention relates to a method and arrangement useful for the deposition (PVD, CVD) of thin films where RF bias is applied to a pedestal for clamping (chucking) a substrate to said pedestal. RF chucks are commonly known and widely used in the semiconductor industry. They are useful to firmly hold a dielectric substrate such as a silicon wafer on a wafer pedestal or wafer holder without additional mechanical clamping means. The holding force can be turned on and off, which is an advantage in the highly automated processing of semiconductor substrates.

### TECHNICAL BACKGROUND

Applications such as bulk acoustic wave (BAW) or surface acoustic wave (SAW) filters utilizing free-standing membrane structures require +/−50 MPa stress control for certain layers. In order to ensure this constraint not only to wafer-to-wafer uniformity but also overall stress uniformity across the wafer is key. If the film stress varies too much across the structure or wafer, membranes can develop cracks or peel off. In some BAW applications that do not require tight stress control for structural reasons it is nevertheless more than desired to keep tight stress distribution to achieve a uniform coupling coefficient.

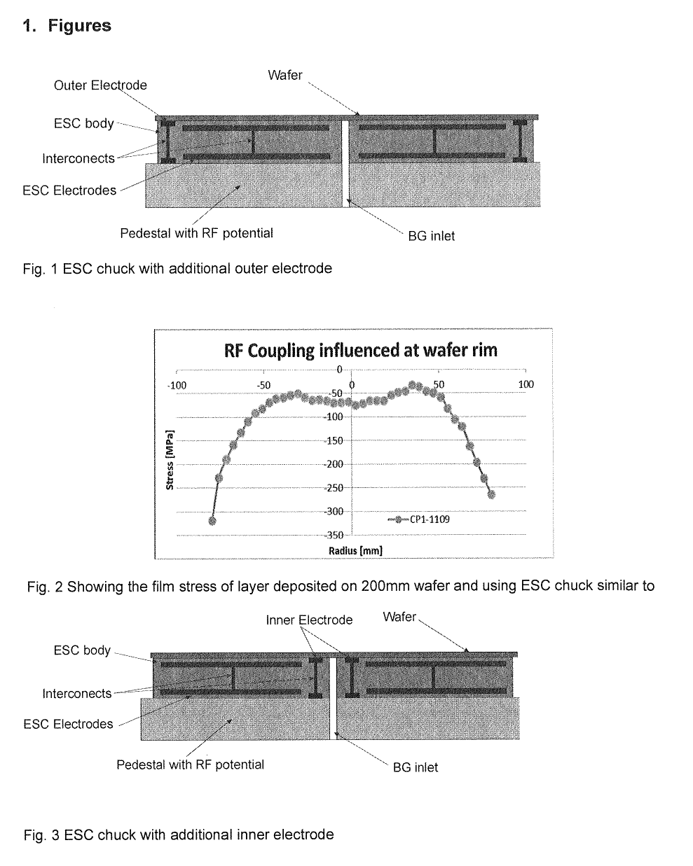

It is common practice to use ESC chucks to control the temperature of the wafer during film etching or deposition. There are two types of ESCs to control the temperature when processing substrates: The Johnson-Rahbeck (J-R) type where the top dielectric layer has a residual conductivity and the Coulomb type, where the top dielectric layer is highly resistive. The Coulomb type has the advantage of having a low leakage current from the electrodes and that the grip force is almost not affected by temperature. One possible embodiment of a Coulomb type ESC is shown in FIG. 1. The way how to build and apply these ESCs is described in US20060043065(A1), US 2006164785 (Semco), US2003-0095370A1, US 20130279066 A1 and other documents. In US 20130284709 A1 the application of an inner and an outer RF electrade embedded in the ESC dielectric puck with a low RF loss are disclosed.

In many applications Coulomb or J-R type ESCs are used in process chambers, where the substrate is processed with a radio frequency (RF). Especially when high RF voltages are applied it was observed that charges accumulate on the top dielectric layer of the ESC. In this case there is the risk that the substrate is not released after processing.

### DISADVANTAGES IN PRIOR ART

One way to achieve very tight control of the stress was presented by Advanced Modular Systems, Inc. This system uses dual magnetron sputtering with AC power applied between the targets and a variable magnetic field. The variable magnetic field which is the vital part of this arrangement to control the stress uniformity is generated by an electromagnet or by permanent magnets moved by an electromotor. It is stated that the stress uniformity can be kept within specifications and also during the entire target life.

The disadvantage of such a system is that in order to improve the stress uniformity and keep it in a specified range, the total deposited thickness of the film (e.g. Aluminum nitride, AlN) is very non-uniform. Therefore this requires another production step and use of trimming modules where the film thickness is trimmed down to meet the specified thickness for example by an ion-beam milling.

### INVENTIVE SOLUTION

In systems where RF power is used for pedestal (chuck) bias application there appears to be another way to influence and control the stress distribution across the entire wafer. An elegant way to control the stress uniformity or distribution across the wafer is by utilizing variations in the RF power coupling path to the wafer. Altering the RF power coupling between wafer (substrate) and pedestal (chuck) on local basis will impact the stress locally. The stronger the RF coupling between wafer and pedestal gets, the more compressive is the built in stress. Consequently, utilizing less or weaker RF coupling will result in the stress of the film to be more tensile. By using this principle the chuck design may contain various composite matrix/pattern of materials with conducting, semi-conducting (differently doped) and/or insulating materials with different dielectric constants (relative permittivity) and thus influence the coupling between chuck and wafer itself resulting in a desired/defined stress profile across the whole wafer.

Major benefits of the a.m. principle are:
It is a hardware solution which decouples the thickness uniformity problem from the film stress uniformity issue. This allows keeping the process parameters open in order to optimize thickness uniformity while stress profile uniformity is taken care of by an inventive chuck with optimized RF coupling to the wafer.
Since the thickness uniformity can already be optimized during the film deposition there is less or no need to apply a subsequent process for trimming the layer thickness to desired values.
This technique can be used for stress control in various film deposition arrangements and types of films. Below we show data with, reactive PVD sputtering and AlN films, but this shall not be limiting to the general inventive principle.

### DETAILED DESCRIPTION OF THE INVENTIVE SOLUTION

The inventive concept can be realized by using an electrostatic chuck (ESC) where different electrodes are embedded in a non-conductive body and thus influence/modify the capacitive or conductive RF power coupling to the wafer and as a result modify the deposited film stress.

A simple schematic is shown in FIG. 1 where a pedestal on RF potential together with an ESC chuck is shown. Inside the ESC body ESC electrodes are shown which couple RF power to the wafer and plasma capacitively. There is an additional outer electrode shown which couples the RF power to the wafer as well. The shape of the additional electrode can vary depending on the shape of the chuck (square, circle). Since normally wafers have circular character first a circular electrode shall be considered which is oriented concentrically to the wafer centre. In first approximation one can take this electrode material as a conductor with certain impedance. However the material type of this electrode can vary in order to influence RF coupling in desired way.

FIG. 2 shows the resulting film stress across a 200 mm wafer. Wafer stress on the rim of the wafer is more compressive than in the centre of the wafer.

FIG. 3 depicts a similar arrangement as FIG. 1 with an additional electrode. Said additional (inner) electrode is located in the center area to emphasize the impact of the altered RF coupling.

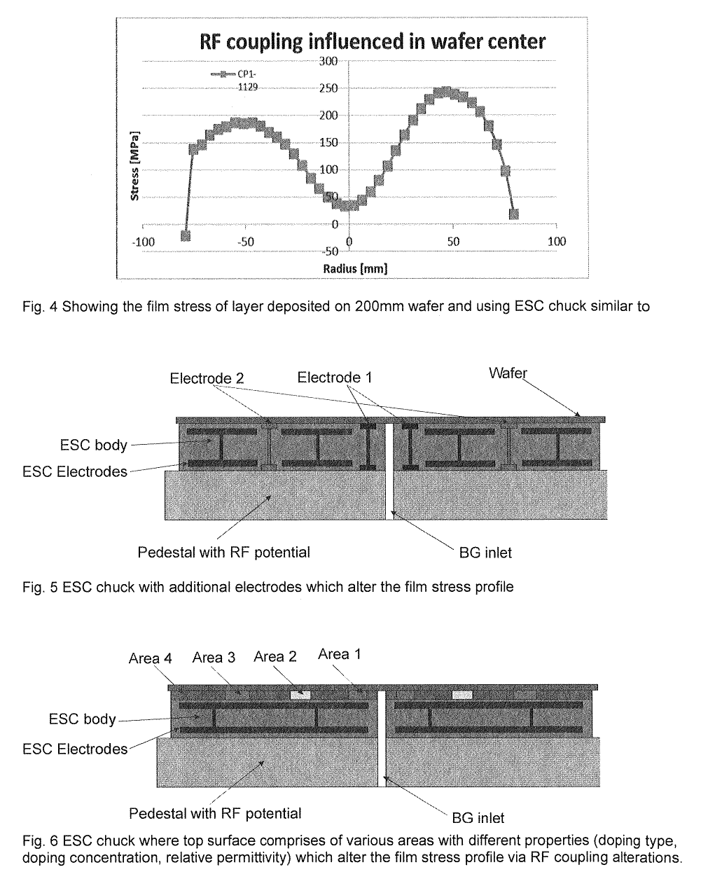

FIG. 4 shows the resulting film stress across a 200 mm wafer corresponding to chuck arrangement in FIG. 3. The film stress in the center of the wafer is much more compressive in comparison to FIG. 2. Consequently, adding more RF coupling centres/areas to the chuck body will result in decreasing the overall range of the film stress across the wafer and thus achieve the desired specified values. This is schematically shown in FIG. 5 where in addition to ESC electrodes further electrodes 1 and 2 are built in thus impacting the areas where predominantly tensile stress would be expected. Improving the RF coupling in these, tensile stress areas will result in more compressive film stress and thus the overall range of film stress across the entire wafer will be smaller which is highly desired. The electrodes 1 and 2 can be of different materials and/or compositions, whose impedance/reactance modifies the RF coupling.

Instead of improving the RF coupling path one also can decouple or screen (shield) the RF from those areas, which will result also in a film stress modification (Fig not shown). For example, one could arrange electrodes in the chuck body which are on ground potential (or any given potential which is not connected to RF field) and thus de couple the RF field form certain areas, lower the impact of RF bias in these screened/shielded areas which again will influence the stress of the deposited layer locally.

Electrodes do not have to be concentrically arranged towards pedestal/chuck or wafer center. In another embodiment a plurality of electrodes organized in a certain pattern (e.g. tiles (square, rectangular), checkerboard, stripes) can be arranged which will result in a desired film stress profile. This can be determined based on the inventive principle with a view on the given substrate/chuck configuration, in other words will be adapted accordingly to round (circular), rectangular or square substrates.

Another alternative to the inventive principle is to use an ESC chuck with differently doped regions and/or matrix of conductive/insulating materials which modulate impedance and thus influence the RF coupling to the wafer. This is principally shown in FIG. 6 where each Area (Area 1 to 4) coupling RF power to the wafer has different properties. The properties can vary for example in doping, dielectric constant (relative permittivity) which influences the impedance, reactance and thus alters the RF coupling and eventually result in variations in film stress. This principle can be simply applied in J-R ESC chucks.

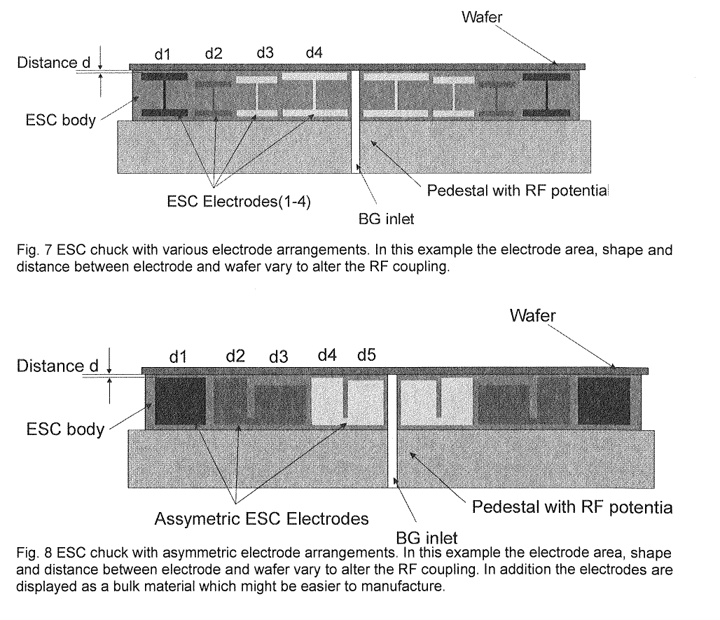

A complimentary approach can be to just alter the RF capacitive coupling across the wafer/pedestal interface by varying the distance between ESC electrodes which are transferring the RF field and wafer. This approach is shown in FIG. 7. Here the distance “d” between ESC electrode and wafer is intentionally altered to increase or decrease the RF field influence. Picture shows 4 ESC electrodes with different distances to the wafer (d1≠d2≠d3≠d4).

Furthermore to achieve desired stress control there is no need for a (size-wise) symmetry between top and bottom electrodes; asymmetric electrodes offer an equivalent benefit as described above. This is schematically shown in FIG. 8 where different shapes of top electrodes in comparison with bottom electrodes are shown. The distance variation (d1≠d2≠d3≠d4≠d5) is also shown as in FIG. 7. In addition the ESC electrodes could be manufactured by various techniques. The screen-printing technique can be applied and creating interconnects (vias) between top and bottom electrodes to conduct the RF signal. Alternatively these electrodes can be made very bulky from different metallic (conductive) materials and bonded with the ESC body and/or use special processes (like sintering) where by means of doping of the non-conductive base/body material the conductive electrodes are created from ceramic type materials. The bulk electrodes are also schematically shown in FIG. 8

An alternative method can be delivering different level of RF power to various locations across the wafer. This can be realized by using two or more RF generators or supplying the same level of the RF power from RF generator and utilizing different attenuations in the RF line to vary the RF power. Of course the transmission line must contain RF matching to adopt the impedance to be able to couple the RF power into the plasma. In case of more than one RF generator is used the phase shift unit (Master oscillator) should be used to avoid the interference and standing waves.

This invention does not address how a high voltage potential and/or a specific waveform is being generated, fed in or distributed which may be necessary for wafer clamping in specific ESC chuck applications. The inventive principle of stress control is broad and can therefore be applied to mono-polar, bi-polar and multipolar ESC chucks.

Furthermore this invention is not limited to ESC chucks, if for example a high clamping force is not required. One can also use the Proposed pedestal design with embedded electrodes as a passive pedestal without applying the high voltage to ESC electrodes where only the RF coupling will be used to alter stress of the films. These passive chucks with no active clamping force will exhibit lower efficiency in RF coupling but the stress control principle is still applicable.

In consequence and summary, a fixture or clamp for a vacuum treatment system, comprising a body with a first plane surface for arranging a substrate such as a wafer thereon and a second surface opposite to said first surface, said body comprising a plurality of electrode-pairs; each electrode pair comprising a first electrode with a first electrode surface and a second electrode with a second electrode surface, said electrode surfaces interconnected via a conductive means and arranged, essentially in parallel to said first and second surface, said first electrode located closer to said first surface than said second electrode and said second electrode located closer to said second surface than said first electrode. A fixture wherein said electrode pairs are arranged side by side, a first electrode completely surrounding a second electrode pair. A fixture wherein the electrode pairs are arranged concentrically around a common symmetry axis.

A fixture wherein the electrode pairs essentially have a shape like
A square
A rectangle
A circle
A circular ring

A fixture wherein the electrode pairs are arranged side by side in
a checkerboard pattern
an irregular pattern of tile-shaped electrode surfaces
a strip next to another strip
a combination of said variants

A fixture wherein at least one area of an electrode or electrode pair is different from the other.

A fixture wherein a distance d is being chosen to describe the effective distance between an electrode surface close to said first surface and the surface of a substrate adjacent to said first surface; said distance being different for at least one of the electrode pairs from all other electrode pairs in the ESC body.

A fixture with a body wherein on one of the surfaces a material layer is being arranged with locally varying material properties resulting in locally varying RF coupling properties.

A fixture with a body with locally varying RF coupling properties due to material variations of said body.

An electrostatic chuck (ESC) comprising a pedestal which can be operatively connected with an RF source in order to establish RF potential/RF bias voltage; said pedestal comprising a surface; a body as described above with its second surface arranged adjacent said pedestal's surface, thus being able to modify the RF coupling properties between the pedestal and said substrate by means of the features described above.

Use of a fixture as described above in a vacuum treatment system to clamp a substrate at least during treating said substrate in a vacuum deposition, heat treatment or alike to achieve a predefined film stress profile/distribution.

Use of a fixture as described above as part of an ESC in a vacuum treatment system to clamp a substrate at least during treating said substrate in a vacuum deposition, heat treatment or alike to achieve a predefined film stress profile/distribution.

A process for treating a substrate in a vacuum treatment system, comprising a fixture for clamping a substrate to be treated, said fixture having properties as described above.

A process for treating a substrate in a vacuum treatment system, comprising an ESC for clamping a substrate to be treated, said ESC having a fixture with properties as described above.

It goes without saying that the functional or material feature may be combined as technically reasonable or advantageous. The fact that the features are listed shall enhance their understanding and does not mean they are not combinable or represent a waiver of combinability.

### SUMMARY

Using variation in RF coupling between wafer and pedestal to achieve a uniform film stress profile/distribution during film deposition.

A chuck/pedestal which has two or more different ways (called paths) to couple RF power bias to the wafer and alter the desired film stress profile.
The RF paths can use capacitive and/or direct conductive coupling or their combinations.
Where each RF path is supplied with different RF power level by separate RF source.
Where each RF path is supplied with different RF power level by using a corresponding attenuation.

A chuck/pedestal which surface/interface with wafer comprises of areas with different properties in order to vary the RF coupling.
The properties of the regions can vary in size of the surface area, doping type, doping concentration and/or relative permittivity to alter the capacitive RF coupling

A chuck/pedestal which alters the capacitive RF coupling by varying the distance between wafer and ESC/RF electrodes by means of using different thickness of the dielectric material.
The combination of altering thickness of the dielectric as well as relative permittivity should be also included.

1. A fixture or clamp for a vacuum treatment system with a non-conductive body with a first plane surface for arranging a substrate such as a wafer thereon and a second surface opposite to said first surface, said body comprising a plurality of electrode-pairs; each electrode pair comprising a first electrode with a first electrode surface and a second electrode with a second electrode surface, said electrode surfaces interconnected via a conductive means and arranged essentially in parallel to said first and second surface, said first electrode located closer to said first surface than said second electrode and said second electrode located closer to said second surface than said first electrode.

2. A fixture according to claim 1, wherein said electrode pairs are arranged side by side, a first electrode completely surrounding a second electrode pair.

3. A fixture according to claim 2, wherein the electrode pairs are arranged concentrically around a common symmetry axis.

4. A fixture according to claim 1, wherein the electrode pairs essentially have the shape of
A square;
A rectangle;
A circle; or
A circular ring

5. A fixture according to claim 1, wherein the electrode pairs are arranged side by side in
a checkerboard pattern
an irregular pattern of tile-shaped electrode surfaces
a strip next to another strip
a combination of said variants

6. A fixture according to claim 1, wherein at least one area of an electrode or electrode pair is different from the other.

7. A fixture according to claim 1, wherein a distance “d” is being chosen to describe the effective distance between an electrode surface close to said first surface and the surface of a substrate adjacent to said first surface; said distance being different for at least one of the electrode pairs from all other electrode pairs in the ESC body.

8. A fixture with a body according to claim 1, wherein on one of the surfaces a material layer is being arranged with locally varying material properties resulting in locally varying RF coupling properties.

9. An electrostatic chuck (ESC) comprising a pedestal operatively connected with an RF source in order to establish a RF potential or RF bias voltage; said ESC comprising a fixture according to claim 1.

10. Use of a fixture according to claim 1 in a vacuum treatment system to clamp a substrate at least during treating said substrate in a vacuum deposition process, in a heat treatment or alike to achieve a predefined film stress profile/distribution.

11. Use of a fixture according to claim 10 as part of an ESC in a vacuum treatment system to clamp a substrate at least during treating said substrate in a vacuum deposition, in a heat treatment or alike to achieve a predefined film stress profile/distribution.

12. A process for treating a substrate in a vacuum treatment system, comprising a fixture according to claim 1 for clamping a substrate to be treated.

13. A process for treating a substrate in a vacuum treatment system, comprising an ESC for clamping a substrate to be treated, said ESC having a fixture according to claim 1.
